(19) United States
(12) Patent Application Publication
(10) Pub. No.: US 2025/0374638 A1
(43) Pub. Date: Dec. 4, 2025

(54) SEMICONDUCTOR DEVICE

(71) Applicant: Samsung Electronics Co., Ltd., Suwon-si (KR)

(72) Inventors: Seung Min CHA, Suwon-si (KR); Min Chan GWAK, Suwon-si (KR); Sang Cheol NA, Suwon-si (KR); Kyoung Woo LEE, Suwon-si (KR)

(73) Assignee: Samsung Electronics Co. Ltd., Suwon-si (KR)

(21) Appl. No.: 19/022,270

(22) Filed: Jan. 15, 2025

(30) Foreign Application Priority Data
Jun. 4, 2024 (KR) 10-2024-0072969

(51) Int. Cl. H10D 64/23; H10D 30/00; H10D 30/01; H10D 30/43; H10D 62/10; H10D 62/13; H10D 64/68; H10D 84/01; H10D 84/83

(52) U.S. Cl. CPC H10D 64/258; H10D 30/43; H10D 30/501; H10D 62/121; H10D 62/151; H10D 64/256; H10D 64/693; H10D 84/832; H10D 30/014; H10D 30/019; H10D 84/0149; H10D 84/0151

(57) ABSTRACT

A semiconductor device includes a lower interlayer insulating layer including a first surface and a second surface that are opposite to each other in a first direction; a plurality of active patterns disposed on the first surface of the lower interlayer insulating layer; a gate structure disposed on the first surface of the lower interlayer insulating layer; a source/drain pattern connected to the plurality of active patterns; a lower conductive layer that is disposed on the second surface of the lower interlayer insulating layer and includes a first surface and a second surface; a lower source/drain contact protruding from the lower conductive layer in the first direction and connected to the source/drain pattern; and a contact separation pattern that penetrates the lower conductive layer and is in contact with the lower interlayer insulating layer.

### CROSS-REFERENCE TO RELATED APPLICATION

This application claims priority from Korean Patent Application No. 10-2024-0072969 filed on Jun. 4, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure generally relates to a semiconductor device, more specifically, to a semiconductor device having improved performance and reliability.

### Description of the Related Art

As one of scaling technologies for increasing density of a semiconductor device, a multi gate transistor in which a multi-channel active pattern (or a silicon body) having a fin or nanowire shape is formed on a substrate and a gate is formed on a surface of the multi-channel active pattern has been proposed.

Since such a multi gate transistor utilizes a three-dimensional channel, scaling is easily performed. Further, even if a gate length of the multi gate transistor is not increased, the current control capability may be improved. Furthermore, a short channel effect (SCE) in which potential of a channel region is influenced by a drain voltage may be effectively suppressed.

On the other hand, there is a need for reducing the capacitance between contacts in the semiconductor device and ensuring electrical stability, as a pitch size of semiconductor device decreases.

### SUMMARY

Example embodiments of the present disclosure provide a semiconductor device having improved performance and reliability.

According to some embodiments of the present disclosure, there is provided a semiconductor device comprising a lower interlayer insulating layer which includes a first surface and a second surface that are opposite to each other in a first direction, a plurality of active patterns which are disposed on the first surface of the lower interlayer insulating layer and spaced apart in the first direction, a gate structure which is disposed on the first surface of the lower interlayer insulating layer, wraps each active pattern, and includes a gate electrode and a gate insulating film, a source/drain pattern connected to the plurality of active patterns, a lower conductive layer which is disposed on the second surface of the lower interlayer insulating layer, and includes a first surface and a second surface that are opposite to each other in the first direction, the first surface of the lower conductive layer being in contact with the lower interlayer insulating layer, a lower source/drain contact which protrudes from the lower conductive layer in the first direction and is connected to the source/drain pattern and a contact separation pattern which penetrates the lower conductive layer to come into contact with the lower interlayer insulating layer, and overlaps the gate structure in the first direction.

According to some embodiments of the present disclosure, there is provided a semiconductor device comprising a lower interlayer insulating layer which includes a first surface and a second surface that are opposite to each other in a first direction, a plurality of active patterns which are disposed on the first surface of the lower interlayer insulating layer, and spaced apart from each other in the first direction, a gate structure which is disposed on the first surface of the lower interlayer insulating layer, wraps each of the active patterns, and includes a gate electrode and a gate insulating film, a first source/drain pattern and a third source/drain pattern which are disposed with the plurality of active patterns interposed therebetween, a first lower conductive layer which is disposed on the second surface of the lower interlayer insulating layer, and overlaps the first source/drain pattern in the first direction, a second lower conductive layer which is disposed on the second surface of the lower interlayer insulating layer, and overlaps the third source/drain pattern in the first direction, a lower source/drain contact which protrudes from the first lower conductive layer in the first direction, and is connected to the first source/drain pattern and a contact separation pattern which extends in the first direction, and separates the first lower conductive layer from the second lower conductive layer, wherein the first lower conductive layer includes a first surface and a second surface that are opposite to each other in the first direction, the first surface of the first lower conductive layer comes into contact with the lower interlayer insulating layer, the second surface of the first lower conductive layer is coplanar with a bottom face of the contact separation pattern, and a height of the contact separation pattern is smaller than a height from the second surface of the first lower conductive layer to a lowermost part of the gate structure.

According to some embodiments of the present disclosure, there is provided a semiconductor device comprising a lower conductive layer, a lower interlayer insulating layer which is disposed on an upper surface of the lower conductive layer, a plurality of active patterns which are disposed on the lower interlayer insulating layer, and spaced apart from the lower interlayer insulating layer in a first direction, a gate structure which is disposed on the lower interlayer insulating layer, wraps each active pattern, and includes a gate electrode and a gate insulating film, a source/drain pattern which is disposed on a side surface of the plurality of active patterns, the source/drain pattern including a first source/drain pattern and a second source/drain pattern spaced apart from the first source/drain pattern in a second direction, an insulating liner which extends along a profile of the source/drain pattern and the gate structure, between the lower interlayer insulating layer and the source/drain pattern, and between the lower interlayer insulating layer and the gate structure, a lower source/drain contact which protrudes from the lower conductive layer, penetrates the lower interlayer insulating layer, and is connected to the source/drain pattern, a contact separation pattern which penetrates the lower conductive layer, overlaps the gate structure in the first direction, and does not come into contact with the gate structure, an element separation film which is spaced apart from the source/drain pattern in the second direction, and penetrates the lower interlayer insulating layer and the lower conductive layer; and an element separation pattern which is disposed between the first source/drain pattern and the second source/drain pattern, and penetrates the lower interlayer insulating layer and the conductive layer, wherein the insulating liner extends along a part of a side surface of the element separation film and a part of a side surface of the element separation pattern.

Embodiments of the present disclosure are not limited to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, in which:

FIG. 1 is an example layout diagram illustrating a semiconductor device according to some embodiments of the present disclosure.

FIG. 2 is a cross-sectional view taken along A-A of FIG. 1.

FIG. 3 is a cross-sectional view taken along B-B of FIG. 1.

FIG. 4 is a cross-sectional view taken along C-C and D-D of FIG. 1.

FIGS. 5 and 6 are diagrams illustrating a semiconductor device according to some embodiments of the present disclosure.

FIGS. 7 and 8 are diagrams illustrating a semiconductor device according to some embodiments of the present disclosure.

FIG. 9 is a diagram illustrating a semiconductor device according to some embodiments of the present disclosure.

FIG. 10 is an enlarged view of a portion P of FIG. 9.

FIG. 11 is an enlarged view of a portion Q of FIG. 9.

FIG. 12 is a diagram illustrating a semiconductor device according to some embodiments of the present disclosure.

FIG. 13 is an enlarged view of a portion R of FIG. 12.

FIG. 14 is a diagram illustrating a semiconductor device according to some embodiments of the present disclosure.

FIGS. 15 to 23 are intermediate stage diagrams illustrating a method for manufacturing a semiconductor device according to some embodiments of the present disclosure.

FIG. 24 is an intermediate stage diagram illustrating a method for manufacturing a semiconductor device according to some embodiments of the present disclosure.

FIGS. 25 to 27 are intermediate stage diagrams illustrating a method for manufacturing a semiconductor device according to some embodiments of the present disclosure.

### DETAILED DESCRIPTION

Although terms such as first and second are used to describe various elements or components in the present specification, these elements or components are not limited by these terms. These terms are only used to distinguish a single element or component from other elements or components. Therefore, a first element or component referred to below may be a second element or component within the technical idea of the present disclosure. Further, a lower element or component referred to below may be an upper element or component within the technical concept of the present disclosure.

Hereinafter, the embodiments of the present disclosure will be described in detail with reference to the accompanying drawings. The same reference numerals are used for the same elements in the drawings, and repeated description will not be provided.

Although drawings of a semiconductor device according to some embodiments show a transistor including a nanowire or a nanosheet, and a Multi-Bridge Channel Field Effect Transistor (MBCFET™) as an example, the embodiment is not limited thereto. The semiconductor device according to some embodiments may also be applied to a fin-type field effect transistor (FinFET) including a channel region having a fin-type pattern shape.

The semiconductor device according to some embodiments may include a tunneling field effect transistor (tunneling FET), a three-dimensional (3D) transistor or a vertical field effect transistor (Vertical FET). The semiconductor device according to some embodiments may, of course, include a planar transistor. In addition, the inventive concept of the present disclosure may be applied to a transistor based on two-dimensional material (2D material-based FETs) and a heterostructure thereof.

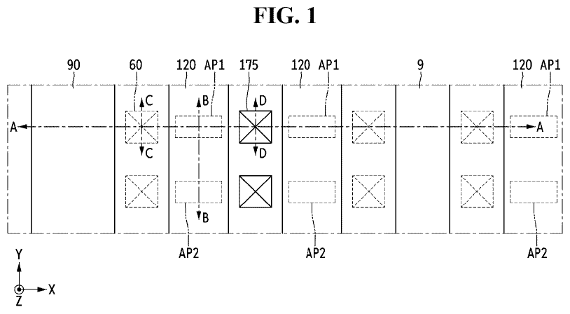

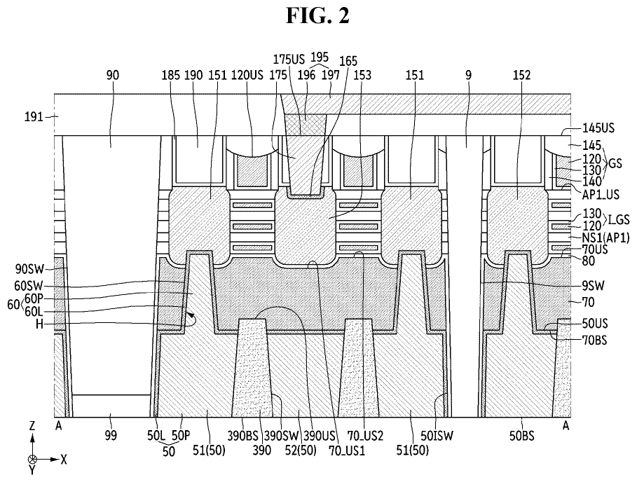

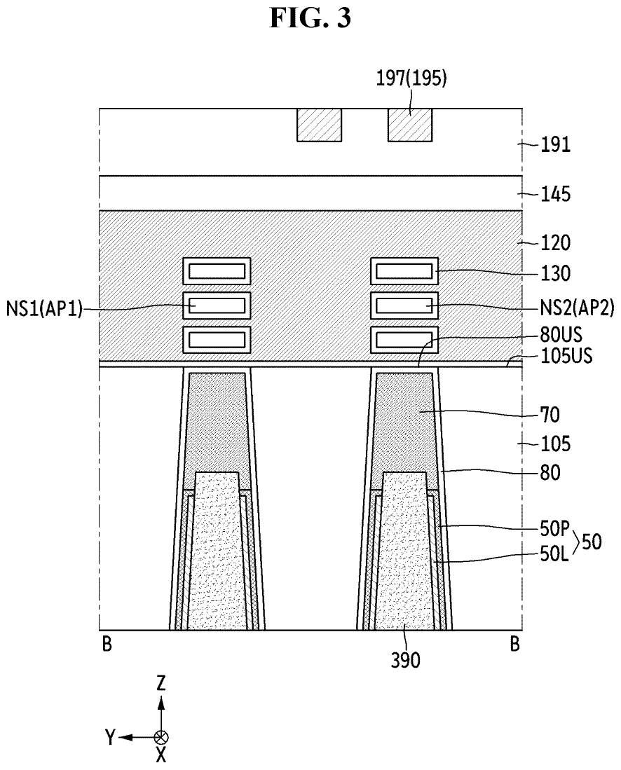

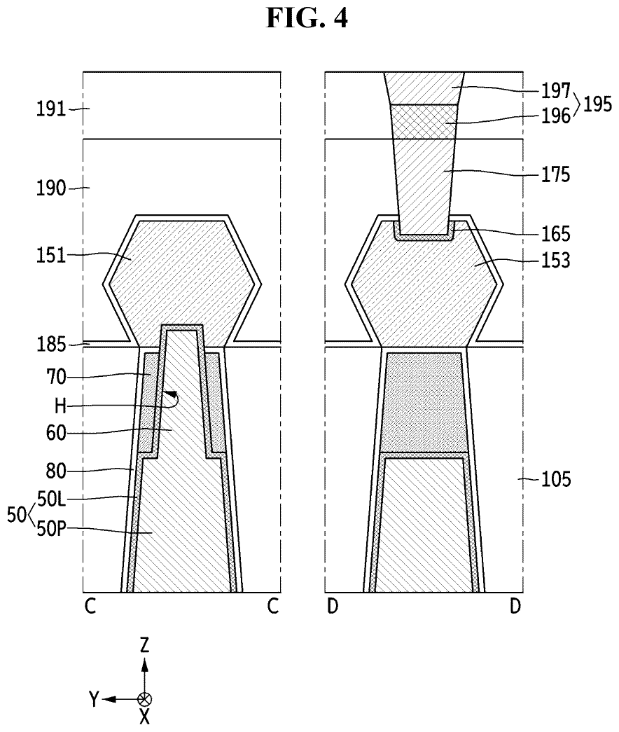

Hereinafter, a semiconductor device according to some embodiments of the present disclosure will be described with reference to FIGS. 1 to 4. FIG. 1 is an example layout diagram illustrating a semiconductor device according to some embodiments of the present disclosure. FIG. 2 is a cross-sectional view taken along A-A of FIG. 1. FIG. 3 is a cross-sectional view taken along B-B of FIG. 1. FIG. 4 is a cross-sectional view taken along C-C and D-D of FIG. 1.

Referring to FIGS. 1 to 4, the semiconductor device according to some embodiments of the present disclosure may include a lower interlayer insulating layer 70, a first active pattern AP1, a second active pattern AP2, a plurality of gate structures GS, a first source/drain pattern 151, a second source/drain pattern 152, a third source/drain pattern 153, an insulating liner 80, a lower conductive layer 50, a lower source/drain contact 60, an upper source/drain contact 175, a contact separation pattern 390, an element separation film 90, an element separation pattern 9, and an upper wiring structure 195.

The lower interlayer insulating layer 70 may extend in a first direction X. The lower interlayer insulating layer 70 may include an upper surface 70US and a lower surface 70BS that are opposite to each other in a third direction Z. The upper surface 70US of the lower interlayer insulating layer 70 may be referred to as a first surface, and the lower surface 70BS of the lower interlayer insulating layer 70 may be referred to as a second surface. The upper surface 70US of the lower interlayer insulating layer 70 may include a concave portion 70_US1 and a convex portion 70_US2. The concave portion 70_US1 may overlap source/drain patterns 151, 152, and 153 to be described below in the third direction Z. The concave portion 70_US1 may extend along lower profiles of the source/drain patterns 151, 152, and 153. The convex portion 70_US2 may overlap a gate electrode 120 to be described below in the third direction Z. The convex portion 70_US2 may extend along the lower profile of the gate electrode 120. The upper surface 70US of the lower interlayer insulating layer 70 has the concave portion 70_US1 and the convex portion 70_US2, it may have an uneven shape.

The lower interlayer insulating layer 70 may be surrounded by a field insulating film 105. The lower interlayer insulating layer 70 may overlap the field insulating film 105 in the second direction Y. In this disclosure, the first direction X, the second direction Y, and the third direction Z may intersect each other. The first direction X, the second direction Y, and the third direction Z may be substantially perpendicular to each other.

The lower interlayer insulating layer 70 may include, for example, at least one of: silicon oxide, silicon nitride, silicon oxynitride, or a low dielectric constant material. As an example, the lower interlayer insulating layer 70 may include silicon oxide.

The low dielectric constant material may be, for example, silicon oxide having moderately high carbon and hydrogen, and may be a material such as SiCOH. Because carbon is included in the insulating material, a dielectric constant of the insulating material may decrease. To further lower the dielectric constant of the insulating material, the insulating material may include one or more pores, such as one or more cavities which are filled with gas or air.

The low dielectric constant material may include, for example, but not limited to, at least one of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

The first active pattern AP1 and the second active pattern AP2 may each be disposed on the lower interlayer insulating layer 70. For example, the first active pattern AP1 and the second active pattern AP2 may each be disposed on the upper surface 70US of the lower interlayer insulating layer 70.

The first active pattern AP1 and the second active pattern AP2 may be disposed to be spaced apart in the second direction Y. The first active pattern AP1 and the second active pattern AP2 may be adjacent to each other in the second direction Y.

The first active pattern AP1 is shown as being closest to the second active pattern AP2 in the second direction Y, but is not limited thereto. In some embodiments, additional active patterns may be disposed between the first active pattern AP1 and the second active pattern AP2.

As an example, the first active pattern AP1 may be a region in which a p-type transistor is formed, and the second active pattern AP2 may be a region in which an n-type transistor is formed. As another example, the first active pattern AP1 and the second active pattern AP2 may be regions in which a p-type transistor is formed. As yet another example, the first active pattern AP1 and the second active pattern AP2 may be regions in which n-type transistors are formed. Hereinafter, the first active pattern AP1 and the second active pattern AP2 will be described as regions in which transistors of different conductive types from each other are formed.

The first active pattern AP1 and the second active pattern AP2 may each be a multi-channel active pattern. The first active pattern AP1 may include a plurality of first sheet patterns NS1. The second active pattern AP2 may include a plurality of second sheet patterns NS2. In the semiconductor device according to some embodiments, the first and second active patterns AP1 and AP2 may each be an active pattern including a nanosheet and a nanowire.

The plurality of first sheet patterns NS1 may be disposed on the lower interlayer insulating layer 70. The plurality of first sheet patterns NS1 may be spaced apart from the lower interlayer insulating layer 70 in the third direction Z. The first sheet pattern NS1 may include an upper surface and a lower surface that are opposite to each other in the third direction Z. The lower surface of the first sheet pattern NS1 may face the lower interlayer insulating layer 70.

The plurality of second sheet patterns NS2 may be disposed on the lower interlayer insulating layer 70. The plurality of second sheet patterns NS2 may be spaced apart from the lower interlayer insulating layer 70 in the third direction Z. Each of the second sheet patterns NS2 may include an upper surface and a lower surface that are opposite to each other in the third direction Z. The lower surface of the second sheet pattern NS2 may face the lower interlayer insulating layer 70.

Although the three first sheet patterns NS1 and the three second sheet patterns NS2 are each shown as being disposed in the third direction Z, this is only for convenience of explanation, and the embodiment is not limited thereto.

The first sheet pattern NS1 may include a first uppermost sheet pattern that is farthest from the lower interlayer insulating layer 70. The upper surface AP1_US of the first active pattern AP1 may be the upper surface of the first uppermost sheet pattern of the first sheet pattern NS1. The description of the second active pattern AP2 and the second sheet pattern NS2 may be substantially the same as the description of the first active pattern AP1 and the first sheet pattern NS1.

Each of the first sheet patterns NS1 and the second sheet patterns NS2 may include one of silicon or germanium, which are elemental semiconductor materials, a group IV-IV compound semiconductor or a group III-V compound semiconductors.

Although a width of each of the first sheet patterns NS1 is shown as being the same, the embodiment is not limited thereto. Each of the first sheet patterns NS1 may be larger or smaller in proportion to a width of the lower interlayer insulating layer 70 in the second direction Y. The width of each second sheet pattern NS2 may be substantially the same as the width of the first sheet pattern NS1.

The field insulating film 105 may be disposed on a side surface of the lower interlayer insulating layer 70 in the second direction Y. The field insulating film 105 may wrap the lower interlayer insulating layer 70. The field insulating film 105 may fill the fin trenches that separate the lower interlayer insulating layers 70 spaced apart in the second direction Y.

The field insulating film 105 may include, for example, an oxide film, a nitride film, an oxynitride film or a combined film thereof. The field insulating film 105 is shown as being a single film, but is not limited thereto. Unlike the shown example, the field insulating film 105 may include a field liner extending along the side walls and bottom face of the fin trench, and a field filling film on the field liner.

A plurality of gate structures GS may be disposed on the upper surface 70US of the lower interlayer insulating layer 70. Each gate structure GS may extend in the second direction Y. The gate structures GS may be disposed to be spaced apart in the first direction X. The gate structures GS may be adjacent to each other in the first direction X.

The gate structure GS may intersect the lower interlayer insulating layer 70. The gate structures GS may intersect a lower conductive layer 50 to be described below. The gate structure GS may wrap each first sheet pattern NS1. The gate structures GS may wrap each second sheet pattern NS2.

The gate structures GS may include, for example, a gate electrode 120, a gate insulating film 130, a gate spacer 140, and a gate capping pattern 145.

The gate structures GS may include a plurality of inner gate structures I_GS disposed between the first sheet patterns NS1 adjacent to each other in the third direction Z and between the lower interlayer insulating layer 70 and the first sheet pattern NS1. The inner gate structures I_GS may be disposed between the upper surface 70US of the lower interlayer insulating layer 70 and the lower surface of the first sheet pattern NS1, and between the upper surface of the first sheet pattern NS1 and the lower surface of the first sheet pattern NS1 that face each other the third direction Z.

The number of the inner gate structures I_GS may be the same as the number of the first sheet patterns NS1. The inner gate structure I_GS may contact with the upper surface 70US of the lower interlayer insulating layer 70, the upper surface of the first sheet pattern NS1, and the lower surface of the second sheet pattern NS2. In the semiconductor device according to some embodiments, the inner gate structure I_GS may contact with the source/drain patterns 151, 152, and 153 as described below.

The inner gate structure I_GS may include a gate electrode 120 and a gate insulating film 130 that are disposed between the adjacent first sheet patterns NS1, and between the lower interlayer insulating layer 70 and the first sheet pattern NS1.

Although not shown, the inner gate structure I_GS may be disposed between the second sheet patterns NS2 adjacent to each other in the third direction Z, and between the lower interlayer insulating layer 70 and the second sheet pattern NS2.

The gate electrode 120 may be disposed on the lower interlayer insulating layer 70. The gate electrode 120 may intersect the lower interlayer insulating layer 70. The gate electrode 120 may wrap the first sheet pattern NS1.

In the cross-sectional view such as FIG. 2, the upper surface 120US of the gate electrode 120 is shown as being a concave curved face, but is not limited thereto. In some embodiments, the upper surface 120US of the gate electrode 120 may be a flat face.

The gate electrode 120 may include at least one of: a metal, a metal alloy, a conductive metal nitride, a metal silicide, a doped semiconductor material, a conductive metal oxide, or a conductive metal oxynitride. The gate electrode 120 may include, for example, but not limited to, at least one of: titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. The conductive metal oxide and conductive metal oxynitride may include, but not limited to, oxidized forms of the above materials.

The gate insulating film 130 may extend along the upper surface 105US of the field insulating film 105 and an upper surface of an insulating liner 80 to be described below. The gate insulating film 130 may wrap a plurality of first sheet patterns NS1. The gate insulating film 130 may wrap a plurality of second sheet patterns NS2. The gate insulating film 130 may be disposed along the periphery of the first sheet pattern NS1 and the periphery of the second sheet pattern NS2. The gate electrode 120 may be disposed on the gate insulating film 130.

The gate insulating film 130 may be disposed between the gate electrode 120 and the first sheet pattern NS1, and between the gate electrode 120 and the second sheet pattern NS2. In the semiconductor device according to some embodiments, the gate insulating film 130 included in the inner gate structure I_GS may contact with the source/drain patterns 151, 152, and 153 as described below.

The gate insulating film 130 may include silicon oxide, silicon oxynitride, silicon nitride or a high dielectric constant material having a dielectric constant higher than that of silicon oxide. The high dielectric constant material may include, for example, at least one of: boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

Although the gate insulating film 130 is shown as being a single film, this is only for convenience of explanation, and the embodiment is not limited thereto. The gate insulating film 130 may include a plurality of films. The gate insulating film 130 may include an interfacial layer and/or a high dielectric constant insulating film which are disposed between the first sheet pattern NS1 and the first gate electrode 120, and between the second sheet pattern NS2 and the first gate electrode 120. For example, the interfacial layer may not be formed along the profile of the upper surface 105US of the field insulating film 105.

The semiconductor device according to some embodiments may include a Negative Capacitance (NC) FET that uses a negative capacitor. For example, the gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitance is lower than the capacitance of each of the individual capacitors. On the other hand, if at least one of the capacitances of two or more capacitors connected in series has a negative value, the overall capacitance may be greater than an absolute value of each of the individual capacitances, while having a positive value.

When the ferroelectric material film having the negative capacitance and the paraelectric material film having the positive capacitance are connected in series, the overall capacitance value of the ferroelectric material film and the paraelectric material film connected in series may increase. By using the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of: hafnium oxide, hafnium zirconium oxide, barium strontium titanium oxide, barium titanium oxide, or lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include at least one doped dopant. For example, the dopant may include at least one of: aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of: gadolinium (Gd), silicon (Si), zirconium (Zr), aluminum (Al), or yttrium (Y).

When the dopant is aluminum (Al), the ferroelectric material film may include 3 to 8 atomic % (at %) aluminum. Here, a ratio of the dopant may be a ratio of aluminum to the sum of hafnium and aluminum. When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but not limited to, at least one of hafnium oxide, zirconium oxide, and aluminum oxide.

The ferroelectric material film and the paraelectric material film may include the same material. In this case, the ferroelectric material film has ferroelectric properties, but the paraelectric material film may not have ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness that ensures ferroelectric properties of the film. The thickness of the ferroelectric material film may be, for example, but not limited to, 0.5 to 10 nm. Since a critical thickness that exhibits ferroelectric properties may vary for each ferroelectric material, the thickness of the ferroelectric material film may vary depending on the ferroelectric material.

As an example, the gate insulating film 130 may include one ferroelectric material film. As another example, the gate insulating film 130 may include a plurality of ferroelectric material films spaced apart from each other. The gate insulating film 130 may have a stacked film structure in which the plurality of ferroelectric material films and the plurality of paraelectric material films are alternately stacked.

The gate spacer 140 may be disposed on the side wall of the gate electrode 120. The gate spacer 140 may not be disposed between the lower interlayer insulating layer 70 and the first sheet pattern NS1, and between the first sheet patterns NS1 adjacent to each other in the third direction Z.

The gate spacer 140 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the gate spacers 140 are each shown as being a single film, this is only for convenience of explanation, and the embedment is not limited thereto.

The gate capping pattern 145 may be disposed on the gate electrode 120. An upper surface 145US of the gate capping pattern 145 may be coplanar with the upper surface of the first upper interlayer insulating layer 190. Unlike the shown example, the gate capping pattern 145 may be disposed between the gate spacers 140.

The gate capping pattern 145 may include, for example, at least one of silicon nitride (SiN), silicon oxynitride (SiON), silicon carbonitride (SiCN), silicon oxycarbonitride (SiOCN), and combinations thereof. The gate capping pattern 145 may include a material having an etching selectivity with respect to the first upper interlayer insulating layer 190.

The source/drain patterns 151, 152 and 153 may be disposed on the lower interlayer insulating layer 70.

The source/drain patterns 151, 152 and 153 may be disposed on the gate electrode 120. The source/drain patterns 151, 152, and 153 may be connected to the first sheet pattern NS1 or the second sheet pattern NS2. The source/drain patterns 151, 152, and 153 may come into contact with the first sheet pattern NS1 or the second sheet pattern NS2.

Each of the source/drain patterns 151, 152, and 153 may include a bottom face that faces the lower interlayer insulating layer 70. The bottom face of each of the source/drain patterns 151, 152, and 153 may come into contact with an insulating liner, which will be described below.

The source/drain patterns 151, 152, and 153 may include at least one dopant doped into the semiconductor material. The first source/drain pattern 151, the second source/drain pattern 152, and the third source/drain pattern 153 may include dopants of the same conductive type.

As an example, the first source/drain pattern 151, the second source/drain pattern 152, and the third source/drain pattern 153 may include a p-type dopant. The P-type dopant may include, but not limited to, at least one of: boron (B) or gallium (Ga). As another example, the first source/drain pattern 151, the second source/drain pattern 152, and the third source/drain pattern 153 may include an n-type dopant. The N-type dopant may include, but not limited to, at least one of: phosphorus (P), arsenic (As), antimony (Sb), or bismuth (Bi).

In FIG. 4, an external form of the first source/drain pattern 151 is shown to be similar to a hexagon, but is not limited thereto. Unlike the shown example, the external form of the first source/drain pattern 151 or the external forms of the second and third source/drain patterns 152 and 153 may be a shape similar to a pentagon or a rectangle.

The first source/drain pattern 151 may be connected to a lower source/drain contact 60, which will be described below. One of the first source/drain patterns 151 may be disposed between an element separation film 90 to be described below and a gate structure GS. The other of the first source/drain pattern 151 may be disposed between an element separation pattern 9 to be described below and a gate structure GS.

The second source/drain pattern 152 may be disposed to be spaced apart from the first source/drain pattern 151 in the first direction X. The second source/drain pattern 152 may be disposed between the element separation pattern 9 and the gate structure GS. The first source/drain pattern 151 may be disposed on one side of the element separation pattern 9, and the second source/drain pattern 152 may be disposed on the other side thereof. The second source/drain pattern 152 may be connected to the lower source/drain contact 60.

The third source/drain pattern 153 may be connected to an upper source/drain contact 175, which will be described below. The third source/drain pattern 153 may be disposed between the adjacent gate structures GS. The third source/drain pattern 153 may not be connected to the lower source/drain contact 60.

A source/drain etch stop film 185 may extend along the outer side wall of the gate spacer 140 and the profile of the first source/drain pattern 151. Although not shown, in some embodiments, the source/drain etch stop film 185 may extend along the profiles of the second source/drain pattern 152 and the third source/drain pattern 153. The source/drain etch stop film 185 may be disposed on the upper surface 70US of the lower interlayer insulating layer 70.

The source/drain etch stop film 185 may include a material having an etching selectivity with respect to a first upper interlayer insulating layer 190 to be described below. The source/drain etch stop film 185 may include, for example, at least one of: silicon nitride (SiN), silicon oxynitride (SiON), silicon oxycarbonitride (SiOCN), silicon boronitride (SiBN), silicon oxyboronitride (SiOBN), silicon oxycarbide (SiOC), or combinations thereof.

The first upper interlayer insulating layer 190 is disposed on the upper surface 70US of the lower interlayer insulating layer 70. The first upper interlayer insulating layer 190 may be disposed on the source/drain patterns 151, 152, and 153. The first upper interlayer insulating layer 190 may not cover the upper surface of the gate capping pattern 145. For example, the upper surface of the first upper interlayer insulating layer 190 may be disposed in the same plane as the upper surface 145US of the gate capping pattern 145.

The first upper interlayer insulating layer 190 may include, for example, at least one of: silicon oxide, silicon nitride, silicon oxynitride, or a low dielectric constant material. The low dielectric constant material may include, for example, but not limited to, at least one of: Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof.

The upper source/drain contact 175 may extend long in the third direction Z. The upper source/drain contact 175 may be connected to the third source/drain pattern 153. For example, the upper source/drain contact 175 may be electrically connected to the third source/drain pattern 153.

The upper source/drain contact 175 is disposed on the upper surface 70US of the lower interlayer insulating layer 70. A height from the upper surface AP1_US of the first active pattern AP1 to the upper surface 175US of the upper source/drain contact 175 may be the same as a height from the upper surface AP1_US of the first active pattern AP1 to the upper surface 145US of the gate capping pattern 145.

The upper source/drain contact 175 may include a conductive material. The upper source/drain contact 175 is shown as being a single film, but is not limited thereto. The upper source/drain contact 175 may have a multi-film structure like a lower conductive layer 50 to be described below.

A contact silicide film 165 may be disposed between the upper source/drain contact 175 and the third source/drain pattern 153. The contact silicide film 165 may include a metal silicide material.

A second upper interlayer insulating layer 191 may be disposed on the first upper interlayer insulating layer 190. The second upper interlayer insulating layer 191 may include, for example, at least one of: silicon oxide, silicon nitride, silicon oxynitride, or a low dielectric constant material.

The upper wiring structure 195 may be disposed inside the second upper interlayer insulating layer 191. The upper wiring structure 195 may include a via plug 196 and a wiring line 197.

The upper wiring structure 195 may be connected to the third source/drain pattern 153. The upper source/drain contact 175 may connect the upper wiring structure 195 and the third source/drain pattern 153. The upper wiring structure 195 may not be connected to the lower source/drain contact 60.

The via plug 196 and the wiring line 197 may each include at least one of, for example, a metal, a metal alloy, a conductive metal nitride, a conductive metal carbide, a conductive metal oxide, a conductive metal carbonitride, or a two-dimensional material.

The via plug 196 and the wiring line 197 are each shown as being a single conductive film structure, but this is only for convenience of explanation, and the embodiment is not limited thereto. Unlike the shown example, as an example, at least one of the via plug 196 or the wiring line 197 may have multiple conductive film structures. As another example, the upper wiring structure 195 may have an integral structure with no interface division between the via plug 196 and the wiring line 197.

The upper wiring structure 195 is shown as being a single film, but is not limited thereto. The upper wiring structure 195 may have a multi-film structure.

The insulating liner 80 may be disposed on the lower interlayer insulating layer 70. Specifically, the insulating liner 80 may be disposed on the upper surface 70US of the lower interlayer insulating layer 70. The insulating liner 80 may extend along the concave portion 70_US1 of the lower interlayer insulating layer 70. The insulating liner 80 may include a concave portion. The insulating liner 80 may extend along the convex portion 70_US2 of the lower interlayer insulating layer 70. The insulating liner 80 may include a convex portion. The insulating liner 80 may have an uneven shape including the concave portion and the convex portion.

The insulating liner 80 may be disposed between the lower interlayer insulating layer 70 and the source/drain patterns 151, 152, and 153. The insulating liner 80 may be disposed between the lower interlayer insulating layer 70 and the gate structure GS.

The insulating liner 80 may come into contact with a side surface 60SW of a lower source/drain contact 60 to be described below. The insulating liner 80 may wrap the lower interlayer insulating layer 70 between the field insulating films 105. The insulating liner 80 may come into contact with the lower interlayer insulating layer 70 between the field insulating films 105. The insulating liner 80 may wrap a lower conductive layer 50 to be described below between the field insulating films 105. The insulating liner 80 may come into contact with the lower conductive layer 50 between the field insulating films 105.

The insulating liner 80 may be made of one or more insulating materials. The insulating liner 80 may include, for example, at least one of: silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), or a low dielectric constant material. As an example, the insulating liner 80 may include silicon nitride.

The lower conductive layer 50 may be disposed on the lower surface 70BS of the lower interlayer insulating layer 70. The lower conductive layer 50 may include an upper surface 50US and a lower surface 50BS that are opposite to each other in the third direction Z. The upper surface 50US of the lower conductive layer 50 may be referred to as a first surface of the lower conductive layer 50. The lower surface 50BS of the lower conductive layer 50 may be referred to as a second surface of the lower conductive layer 50. The first surface of the lower conductive layer 50 may come into contact with the lower interlayer insulating layer 70.

The lower source/drain contact 60 may extend from the lower conductive layer 50 in the third direction Z. The lower source/drain contact 60 extends from the lower conductive layer 50, and may be connected to the first source/drain pattern 151 and the second source/drain pattern 152. The lower source/drain contact 60 may penetrate the lower interlayer insulating layer 70. Specifically, the lower source/drain contact 60 may penetrate the upper surface 70US and the lower surface 70BS of the lower interlayer insulating layer 70. Although it is not shown, the lower source/drain contact 60 may include a silicide film.

The lower conductive layer 50 and the lower source/drain contact 60 may include conductive liner films 50L and 60L and filling films 50P and 60P. The lower conductive layer 50 may include a first hole H extending in the third direction Z. The first hole H may be filled with the conductive liner film 60L and the filling film 60P to form the lower source/drain contact 60. The lower conductive layer 50 and the lower source/drain contact 60 may be an integral structure without an interface.

The conductive liner films 50L and 60L may extend along the inner side surface 50ISW of the lower conductive layer 50 and the inner side surface of the first hole H. Specifically, the conductive liner films 50L and 60L may extend along the edges of the lower conductive layer 50 and the first hole H.

The conductive liner films 50L and 60L may include one or more conductive material, and may for example, at least one of: tantalum (Ta), tantalum nitride (TaN), tantalum nitride doped with ruthenium (Ru) (TaN:Ru), titanium (Ti), titanium nitride (TiN), titanium silicon nitride (TiSiN), tungsten nitride (WN), tungsten carbonitride (WCN), ruthenium (Ru), cobalt (Co), ruthenium-cobalt (RuCo) alloy, zirconium (Zr), zirconium nitride (ZrN), vanadium (V), vanadium nitride (VN), niobium (Nb), niobium nitride (NbN), platinum (Pt), iridium (Ir), or rhodium (Rh).

Filling films 50P and 60P may be disposed on the conductive liner films 50L and 60L. The filling films 50P and 60P may come into contact with the conductive liner films 50L and 60L.

The filling films 50P and 60P include a conductive material, and may include, for example, at least one of: aluminum (Al), copper (Cu), tungsten (W), cobalt (Co), ruthenium (Ru), silver (Ag), gold (Au), manganese (Mn), molybdenum (Mo), rhodium (Rh), iridium (Ir), RuAl, NiAl, NbB2, MoB2, TaB2, V2AlC, or CrAlC.

The lower conductive layer 50 may include a first lower conductive layer 51 that overlaps the first source/drain pattern 151 in the third direction Z, and a second lower conductive layer 52 that overlaps the third source/drain pattern 153 in the third direction Z. The first lower conductive layer 51 and the second lower conductive layer 52 may be separated by a contact separation pattern 390, which will be described below. The first lower conductive layer 51 may include the lower source/drain contact 60, and the second lower conductive layer 52 may not include the lower source/drain contact 60. The first lower conductive layer 51 may be disposed between an element separation film 90 and a contact separation pattern 390, which will be described below. Alternatively, the first lower conductive layer 51 may be disposed between an element separation pattern 9 and a contact separation pattern 390, which will be described below. The second lower conductive layer 52 may be disposed between the contact separation patterns 390.

The contact separation pattern 390 may extend in the third direction Z. The contact separation pattern 390 may include an upper surface 390US and a lower surface 390BS that are opposite to each other in the third direction Z. The contact separation pattern 390 may be disposed to penetrate the lower conductive layer 50. Specifically, the contact separation pattern 390 may penetrate the upper surface 50US and the lower surface 50BS of the lower conductive layer 50. A part of the contact separation pattern 390 may be surrounded by the conductive liner film 50L and the filling film 50P. The lower surface 390BS of the contact separation pattern 390 may be coplanar with the lower surface 50BS of the lower conductive layer 50. The upper surface 390US of the contact separation pattern 390 may be located at a higher level than the upper surface 50US of the lower conductive layer 50. The upper surface 390US of the contact separation pattern 390 may be located at a lower level than the upper surface 70US of the lower interlayer insulating layer 70.

The contact separation pattern 390 may overlap the gate structure GS in the third direction Z. The contact separation pattern 390 may not come into contact with the gate structure GS. The contact separation pattern 390 may overlap the convex portion 70_US2 of the lower interlayer insulating layer 70 in the third direction Z. A part of the contact separation pattern 390 that penetrates the upper surface 50US of the lower conductive layer 50 may overlap the lower source/drain contact 60 in the first direction X.

The contact separation pattern 390 may be made of one or more insulating materials. The contact separation pattern 390 may include, for example, but not limited to, at least one of: silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), or a low dielectric material.

The element separation film 90 may be disposed to be spaced apart from the first source/drain pattern 151 in the first direction X. The element separation film 90 may be disposed to extend in the third direction Z from the first upper interlayer insulating layer 190. The element separation film 90 may extend in the second direction Y.

The element separation film 90 may overlap the lower conductive layer 50, the lower interlayer insulating layer 70, the source/drain patterns 151, 152 and 153, the gate electrode 120, and the first upper interlayer insulating layer 190 in the first direction X.

The element separation film 90 may penetrate the lower interlayer insulating layer 70. The element separation film 90 may penetrate the upper surface 50US of the lower conductive layer 50. An insulating liner 80 may be disposed on the side surface 90SW of the element separation film 90. The insulating liner 80 may extend along the side surface 90SW of the element separation film 90.

The width of the element separation film 90 may become narrower, as it goes away from the second upper interlayer insulating layer 191.

The element separation film 90 may be made of one or more insulating materials. For example, the element separation film 90 may include at least one of: silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), aluminum oxide (AlO), or combinations thereof. The element separation film 90 is shown as being a single film, but is not limited thereto.

A capping insulating film 99 may be disposed on the lower surface of the element separation film 90. The capping insulating film 99 may serve as an etch stop film, and the capping insulating film 99 may overlap the lower conductive layer 50 in the first direction X. An insulating liner 80 may be disposed on a side surface of the capping insulating film 99. That is, the insulating liner 80 may extend along the side surface of the capping insulating film 99.

The capping insulating film 99 may include an insulating material. For example, the capping insulating film 99 may include silicon nitride.

The element separation pattern 9 may be disposed between the first source/drain pattern 151 and the second source/drain pattern 152. The element separation pattern 9 may be disposed to extend from the first upper interlayer insulating layer 190 in the third direction Z. The element separation pattern 9 may extend in the second direction Y. The element separation pattern 9 may separate the first source/drain pattern 151 and the second source/drain pattern 152.

The element separation pattern 9 may overlap the lower conductive layer 50, the lower interlayer insulating layer 70, the source/drain patterns 151, 152 and 153, the gate electrode 120, and the first upper interlayer insulating layer 190 in the first direction X.

The element separation pattern 9 may penetrate the lower interlayer insulating layer 70 and the lower conductive layer 50. The element separation pattern 9 may extend from the lower surface of the second upper interlayer insulating layer 191 to the lower surface 50BS of the lower conductive layer 50. The insulating liner 80 may be disposed on a side surface 9SW of the element separation pattern 9. The insulating liner 80 may extend along the side surface 9SW of the element separation pattern 9.

The width of the element separation pattern 9 may become narrower as it goes away from the second upper interlayer insulating layer 191.

The element separation pattern 9 may be made of one or more insulating materials. For example, the element separation pattern 9 may include, for example, at least one of: silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), or combinations thereof. The element separation pattern 9 is shown as being a single film, but is not limited thereto.

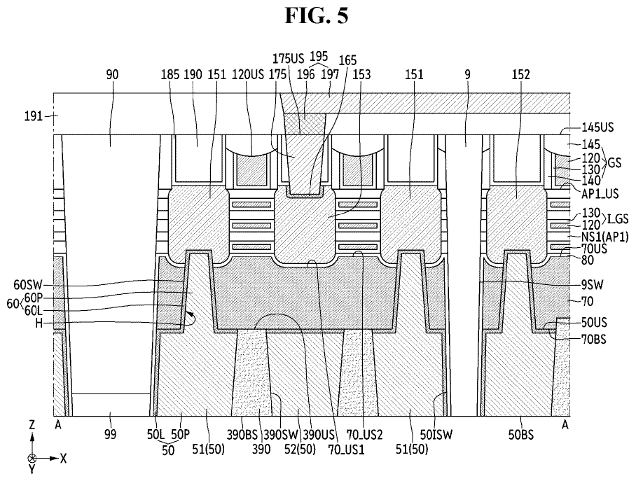

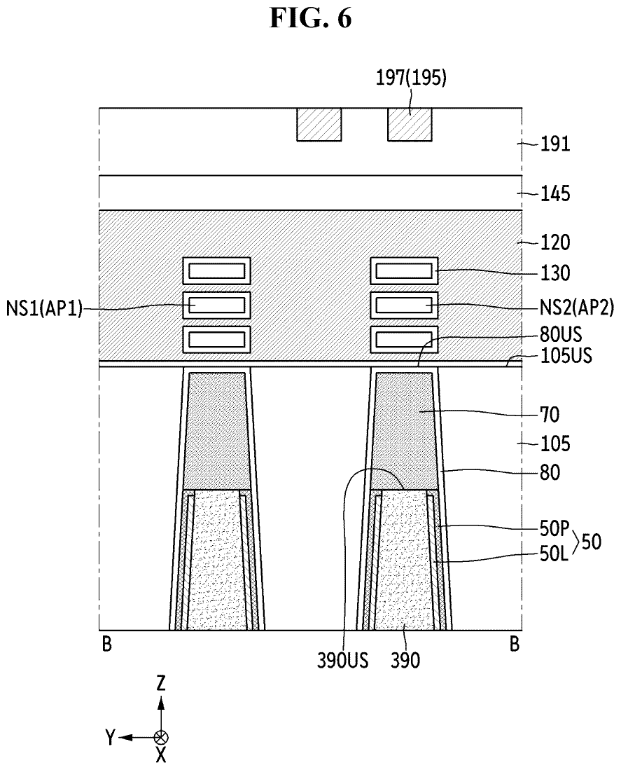

FIGS. 5 and 6 are diagrams for explaining a semiconductor device according to some embodiments of the present disclosure. For convenience of explanation, repeated contents of those explained with respect to FIGS. 1 to 4 will be briefly explained or omitted.

Referring to FIGS. 5 and 6, the upper surface 390US of the contact separation pattern 390 may be coplanar with the upper surface 50US of the lower conductive layer 50.

The upper surface 390US of the contact separation pattern 390 may come into contact with the lower surface 70BS of the lower interlayer insulating layer 70. The contact separation pattern 390 may not penetrate the lower surface 70BS of the lower interlayer insulating layer 70. The upper surface 390US of the contact separation pattern 390 may be located at the same level as the upper surface 50US of the lower conductive layer 50 in reference to the lower surface 50BS of the lower conductive layer 50.

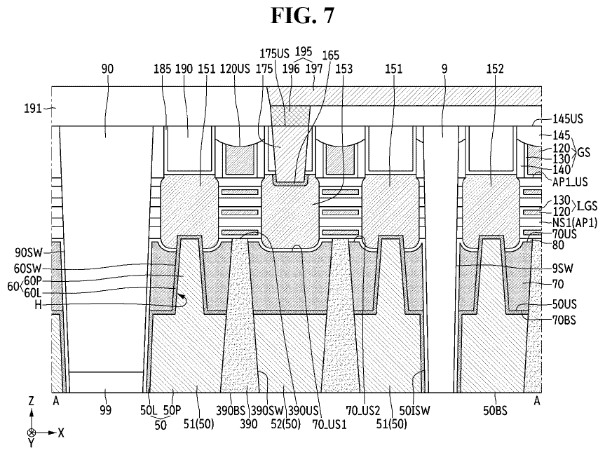

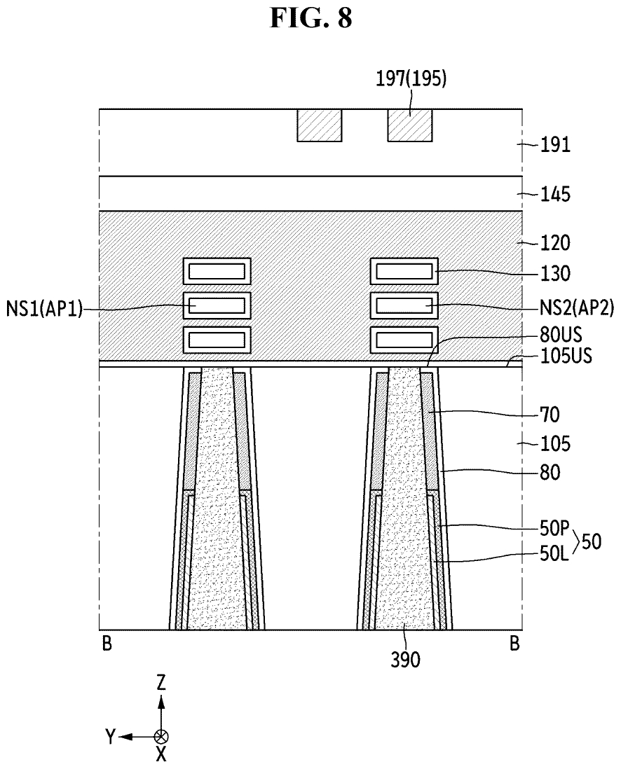

FIGS. 7 and 8 are diagrams for explaining a semiconductor device according to some embodiments of the present disclosure. For convenience of explanation, repeated contents of those explained in FIGS. 1 to 4 will be briefly explained or omitted.

Referring to FIGS. 7 and 8, in some embodiments, the contact separation pattern 390 may extend in the third direction Z and come into contact with the gate structure GS. For example, the contact separation pattern 390 may penetrate the lower conductive layer 50 and the lower interlayer insulating layer 70 and come into contact with the gate structure GS. The contact separation pattern 390 may come into contact with the gate insulating film 130.

The contact separation pattern 390 may come into contact with the insulating liner 80. The contact separation pattern 390 may penetrate the insulating liner 80. The insulating liner 80 may come into contact with a part of the side surface 390SW of the contact separation pattern 390.

The upper surface 390US of the contact separation pattern 390 may be higher than the upper surface 70US of the lower interlayer insulating layer 70. A part of the contact separation pattern 390 may be surrounded by the lower interlayer insulating layer 70.

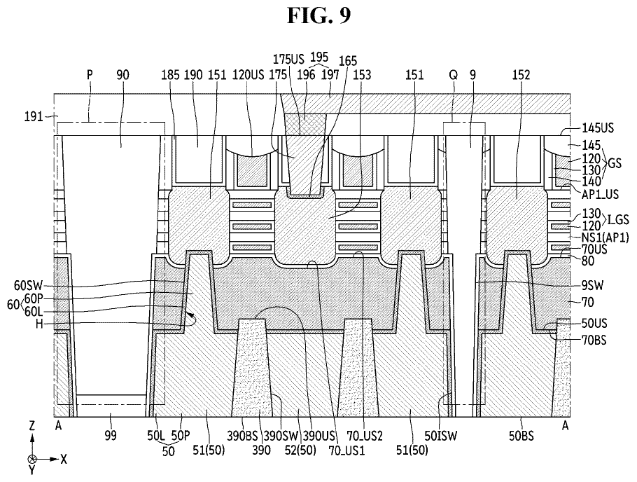

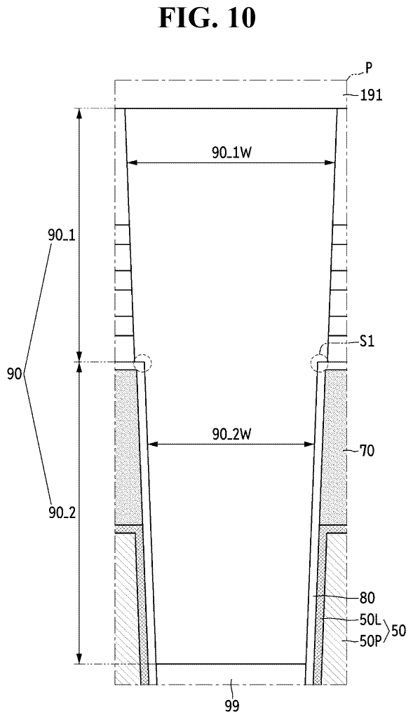

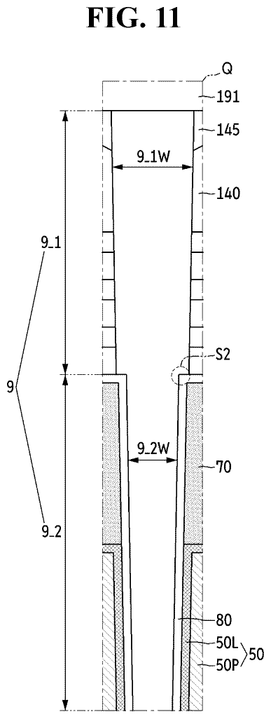

FIG. 9 is a diagram for explaining a semiconductor device according to some embodiments of the present disclosure. FIG. 10 is an enlarged view of a portion P of FIG. 9. FIG. 11 is an enlarged view of a portion Q of FIG. 9. For convenience of explanation, repeated contents of those explained with respect to FIG. 1 to FIG. 4 will be briefly explained or omitted.

The element separation film 90 and the element separation pattern 9 may include a referring to FIGS. 9 to 11.

The element separation film 90 may include a first portion 90_1 and a second portion 90_2 referring to FIGS. 9 and 10.

The element separation film 90 may include a first step S1 in reference to the upper surface of the insulating liner 80. Since the element separation film 90 includes the first step S1, widths 90_1W and 90_2W of the element separation film 90 may be discontinuously narrowed at the first step S1. For example, the width 90_1W of the first portion 90_1 of the element separation film 90 may be continuously narrowed as it goes away from the second upper interlayer insulating layer 191. The width 90_2W of the second portion 90_2 of the element separation film 90 may be continuously narrowed as it goes away from the second upper interlayer insulating layer 191. However, the width of the element separation film 90 may be discontinuously narrowed at the first step S1, which is a boundary between the first portion 90_1 and the second portion 90_2. Since the element separation film 90 includes the first step S1, a part of the insulating liner 80 and the first portion 901 may overlap in the third direction Z.

Referring to FIGS. 9 and 11, the element separation pattern 9 may include a first portion 9_1 and a second portion 9_2.

The element separation pattern 9 may include a second step S2 in reference to the upper surface of the insulating liner 80. Since the element separation pattern 9 includes the second step S2, the widths 9_1W and 9_2W of the element separation pattern 9 may be discontinuously narrowed at the second step S2. For example, the width 9_1W of the first portion 9_1 of the element separation pattern 9 continuously narrows as it goes away from the second upper interlayer insulating layer 191. The width 9_2W of the second portion 9_2 of the element separation pattern 9 may narrow as it goes away from the second upper interlayer insulating layer 191. However, the width of the element separation film 90 may be discontinuously narrowed at the second step S2, which is a boundary between the first portion 9_1 and the second portion 9_2. Since the element separation pattern 9 includes the second step S2, a part of the insulating liner 80 and the first portion 91 may overlap in the third direction Z.

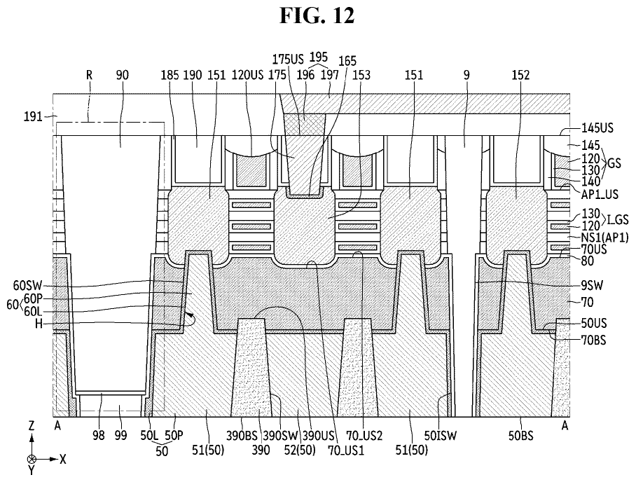

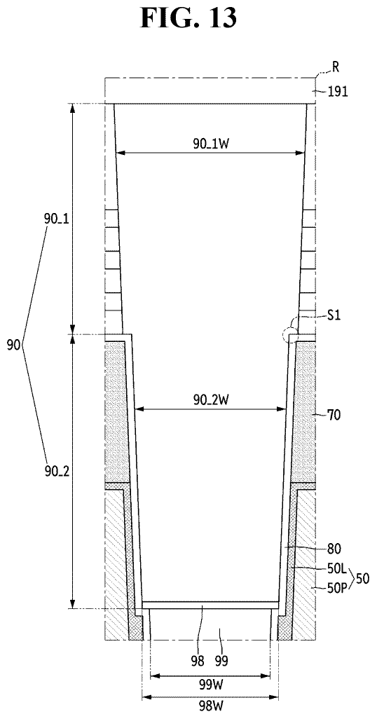

FIG. 12 is a diagram for explaining a semiconductor device according to some embodiments of the present disclosure. FIG. 13 is an enlarged view of a portion R of FIG. 12. For convenience of explanation, repeated contents of those explained in FIGS. 1 to 11 will be briefly explained or omitted.

Referring to FIGS. 12 and 13, the element separation film 90 may include a first portion 90_1 and a second portion 90_2. The first step S1 may be included between the first portion 90_1 and the second portion 90_2.

A capping liner film 98 and a capping insulating film 99 may be disposed on the element separation film 90. The capping liner film 98 may be disposed on the lower surface of the element separation film 90. The capping insulating film 99 may be disposed on the capping liner film 98. A width 99W of the capping insulating film 99 in the first direction X may be smaller than a width 98W of the capping liner film 98 in the first direction X. Thus, the capping insulating film 99 and the capping liner film 98 may have a step.

The capping liner film 98 and the capping insulating film 99 may include an insulating material. The capping liner film 98 and the capping insulating film 99 may include different insulating materials from each other. For example, the capping liner film 98 may include silicon oxide. The capping insulating film 99 may include silicon nitride. The insulating liner 80 may extend along the side surfaces of the capping liner film 98 and the capping insulating film 99.

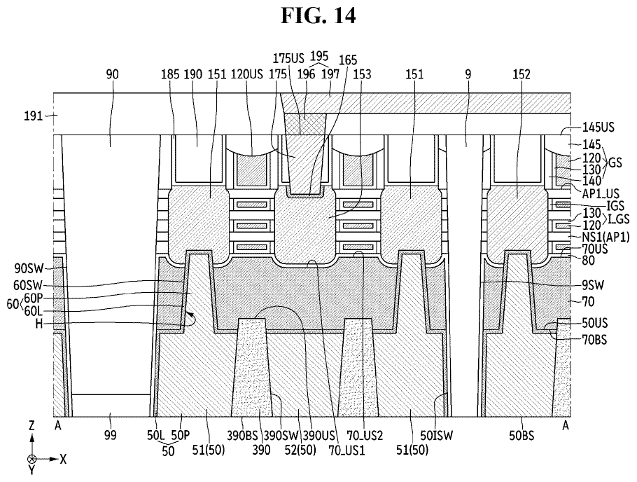

FIG. 14 is a diagram for explaining a semiconductor device according to some embodiments of the present disclosure. For convenience of explanation, repeated contents of those explained with respect to FIGS. 1 to 4 will be briefly explained or omitted.

Referring to FIG. 14, the semiconductor device according to some embodiments may further include an inner gate spacer IGS. The inner gate spacer IGS may be disposed between the source/drain patterns 151, 152 and 153 and the gate electrode 120. The inner gate spacer IGS may be disposed between the source/drain patterns 151, 152 and 153 and the gate insulating film 130. The inner gate spacer IGS may include an insulating material.

As a pitch size of the semiconductor device becomes smaller, it is necessary to ensure electrical stability between contacts in the semiconductor device. For isolation between the lower source/drain contacts 60, a contact separation pattern 390 may be disposed between the lower source/drain contacts 60. When the lower source/drain contact 60 penetrates the doped silicon layer and is connected to the source/drain pattern, leakage current may be generated through the Si layer. In addition, the contact separation pattern 390 may extend up to the gate electrode 120 to prevent leakage current through the Si layer. In this case, the gate electrode 120 may be damaged.

However, in the semiconductor device according to some embodiments of the present disclosure, the lower interlayer insulating layer 70 may be disposed on the lower conductive layer 50. The lower source/drain contact 60 may extend from the lower conductive layer 50 in the third direction Z and penetrate the lower interlayer insulating layer 70. The lower source/drain contact 60 penetrates the lower interlayer insulating layer 70 and may be connected to the first source/drain pattern 151. Since the lower interlayer insulating layer 70 covers the lower source/drain contact 60, leakage current may be prevented from flowing. In addition, because the lower interlayer insulating layer 70 covers the lower source/drain contact 60, the contact separation pattern 390 may not extend up to the gate electrode 120. That is, the contact separation pattern 390 may not come into contact with the gate electrode 120. Therefore, the semiconductor device according to some embodiments of the present disclosure may prevent leakage current from flowing and damage to the gate electrode 120.

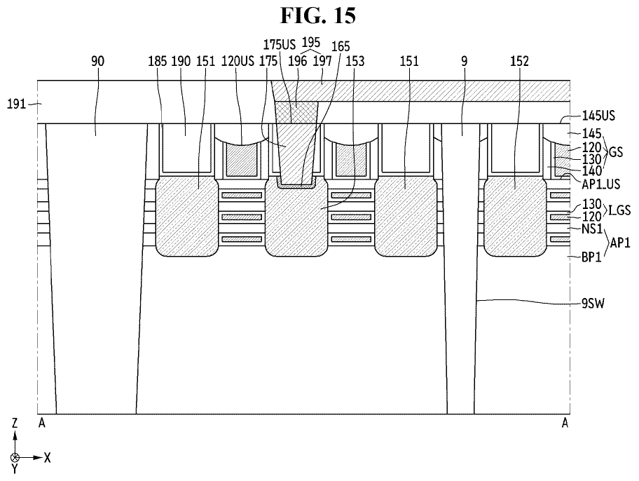

FIGS. 15 to 23 are intermediate stage diagrams for explaining a method for manufacturing a semiconductor device according to some embodiments of the present disclosure. For the convenience of explanation, repeated contents of those explained with respect to FIG. 1 to FIG. 4 will be briefly described or omitted.

Referring to FIG. 15, the first active pattern AP1 may include a lower pattern BP1 and a first sheet pattern NS1. The lower pattern BP1 may include silicon or germanium, which is an elemental semiconductor material. The lower pattern BP1 may also include a compound semiconductor, for example, a group IV-IV compound semiconductor or a group III-V compound semiconductor.

The group IV-IV compound semiconductor may be, for example, a binary compound or a ternary compound including at least two of carbon (C), silicon (Si), germanium (Ge), and tin (Sn), or a compound obtained by doping these elements with a group IV element.

The group III-V compound semiconductor may be, for example, one of a binary compound, a ternary compound or a quaternary compound formed by combining at least one of aluminum (Al), gallium (Ga), or indium (In) as a group III element with one of phosphorus (P), arsenic (As), or antimony (Sb) as a group V element.

The source/drain patterns 151, 152, and 153, the first sheet pattern NS1, the gate structure GS, the upper source/drain contact 175, the upper wiring structure 195, and the first and second upper interlayer insulating layers 190 and 191 may be formed on the lower pattern BP1. The element separation film 90 may extend from the second upper interlayer insulating layer 191 to the lower surface of the lower pattern BP1. The element separation film 90 may extend in the second direction Y. The element separation pattern 9 may extend from the second upper interlayer insulating layer 191 to the lower surface of the lower pattern BP1. The element separation pattern 9 may extend in the second direction Y.

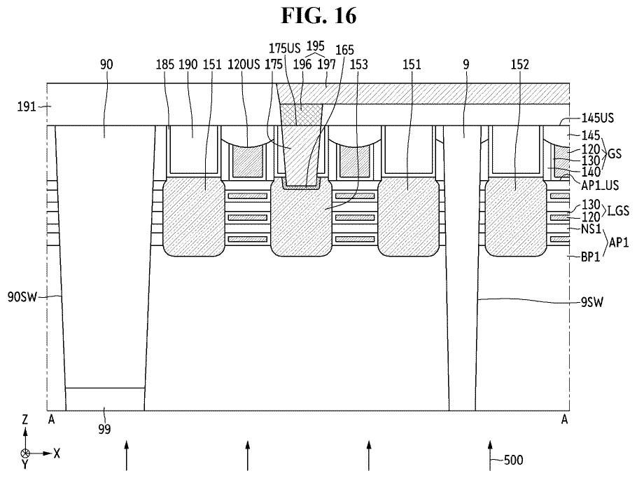

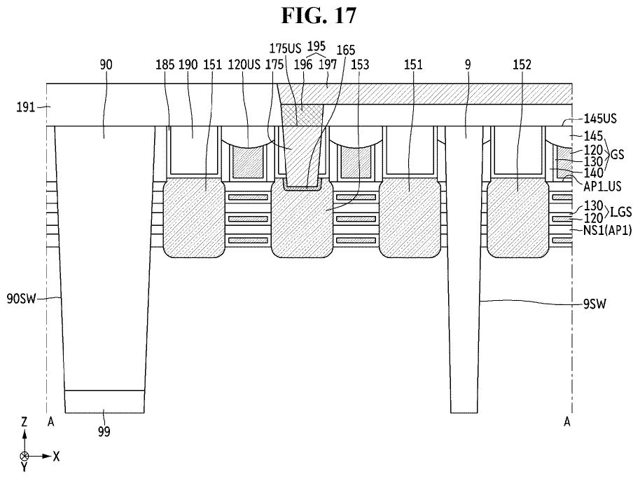

Referring to FIGS. 16 and 17, a part of the lower part of the element separation film 90 is removed and a capping insulating film 99 is formed on the element separation film 90. Then, an etching process 500 is performed to remove the lower pattern BP1.

A part of the lower part of the element separation film 90 may be removed and a capping insulating film 99 may be formed in the location at which the element separation film 90 is removed. The capping insulating film 99 may serve as an etch stop film.

The etching process 500 may be a wet etching process or a dry etching process. The etching process 500 may be performed to remove the lower pattern BP1. The lower pattern BP1 may be removed to expose the first source/drain pattern 151, the second source/drain pattern 152, the third source/drain pattern 153, and the gate insulating film 130.

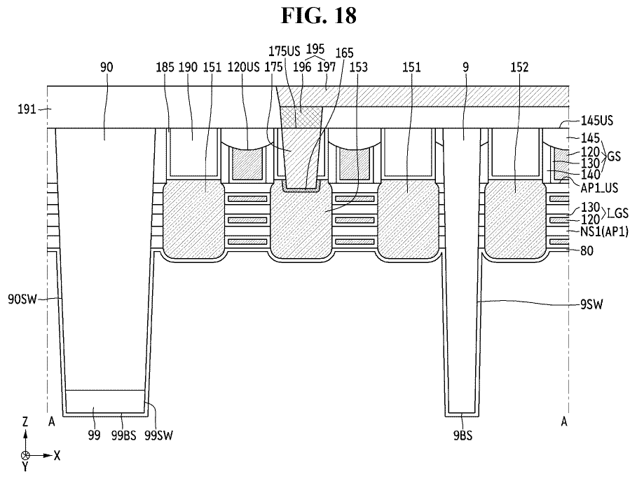

Referring to FIG. 18, an insulating liner 80 is formed.

The insulating liner 80 may be formed along the profile of the exposed source/drain patterns 151, 152, and 153 and the gate insulating film 130. The insulating liner 80 may be formed along the side surface 90SW of the element separation film 90, the side surface 99SW of the capping insulating film 99, the lower surface 99BS of the capping insulating film 99, and the side surface 9SW and the lower surface 9BS of the element separation pattern 9. The insulating liner 80 may include an insulating material.

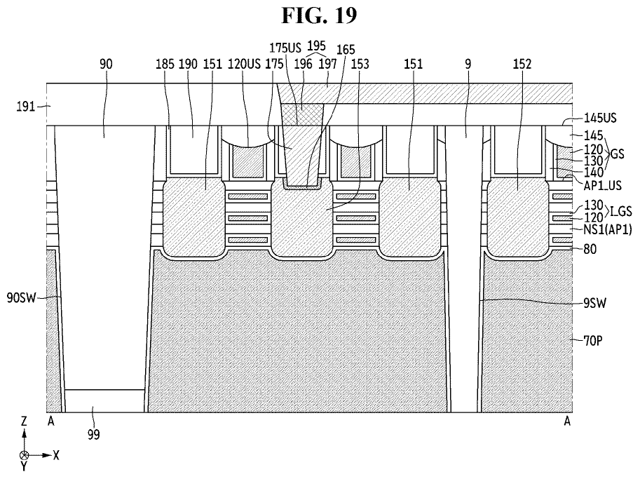

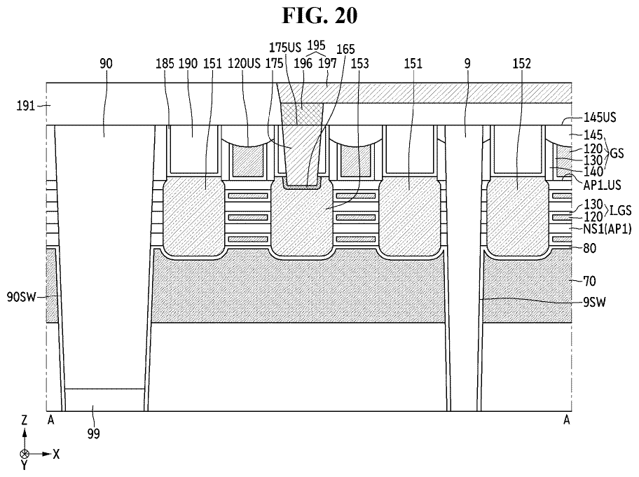

Referring to FIGS. 19 and 20, after forming a pre-lower interlayer insulating layer 70P, a part of the pre-lower interlayer insulating layer 70P is removed to form the lower interlayer insulating layer 70.

A part of the insulating liner 80, a part of the capping insulating film 99, and a part of the element separation pattern 9 may be removed through the planarization process before the pre-lower interlayer insulating layer 70P is formed. The capping insulating film 99 and the element separation pattern 9 may be exposed by the planarization process.

Next, a pre-lower interlayer insulating layer 70P including an insulating material may be formed on the insulating liner 80. Then, a part of the pre-lower interlayer insulating layer 70P may be removed to form the lower interlayer insulating layer 70.

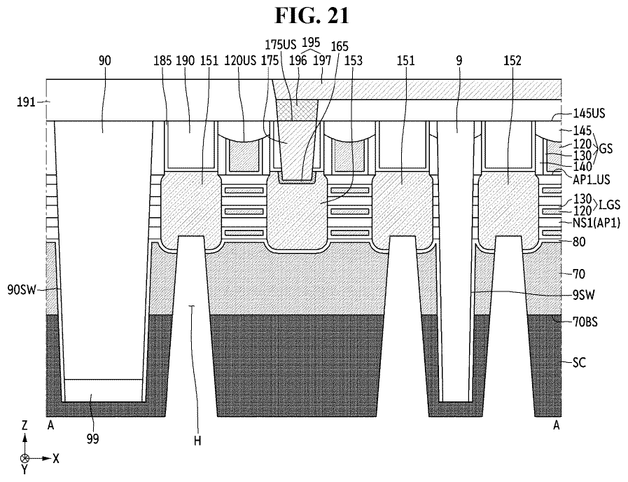

Referring to FIG. 21, a sacrificial film SC is filled on the lower surface 70BS of the lower interlayer insulating layer 70, and a first hole H is formed.

The sacrificial film SC may cover the lower interlayer insulating layer 70, the element separation film 90, the insulating liner 80, the capping insulating film 99, and the element separation pattern 9. The sacrificial film may include Spin On Hardmask (SOH). After the sacrificial film SC is formed, the first hole H extending up to the first source/drain pattern 151 and the second source/drain pattern 152 may be formed. The first hole H may penetrate the sacrificial film SC and the lower interlayer insulating layer 70.

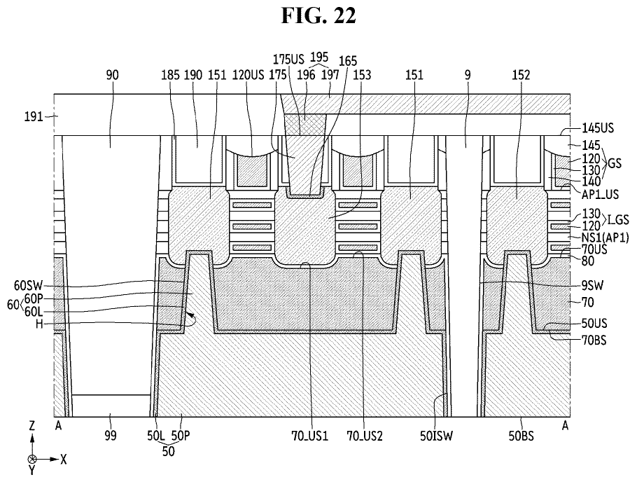

Referring to FIG. 22, the sacrificial film is then removed, and a lower conductive layer 50 is formed at the location where the sacrificial film is removed.

The conductive liner films 50L and 60L may be formed at the location where the sacrificial film SC is removed and at the first hole H, and filling films 50P and 60P may be formed on the conductive liner films 50L and 60L.

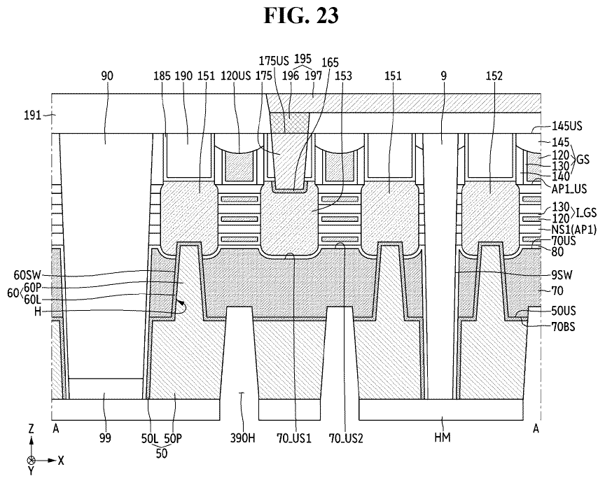

Referring to FIG. 23, a contact separation hole 390H is then formed.

The contact separation hole 390H may be formed using a hard mask HM, and the contact separation hole 390H may overlap the gate electrode 120 in the third direction Z. The contact separation hole 390H may penetrate the lower conductive layer 50. The contact separation hole 390H may extend in the third direction Z. The contact separation hole 390H may not come into contact with the gate electrode 120. The contact separation hole 390H may penetrate the lower surface 70BS of the lower interlayer insulating layer 70. The contact separation hole 390H may be inserted into the lower interlayer insulating layer 70.

Then, the contact separation hole 390H may be filled with an insulating material to form a contact separation pattern 390, thereby forming the product of FIG. 2.

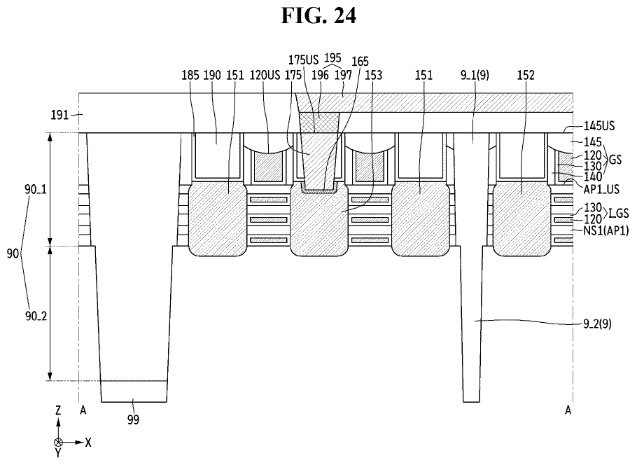

FIG. 24 is an intermediate stage diagram for explaining a method for manufacturing a semiconductor device according to some embodiments of the present disclosure. For convenience of explanation, the repeated contents of those explained with respect to FIGS. 15 to 23 will be briefly explained or omitted. FIG. 24 is a diagram showing the procedure after FIG. 17.

Referring to FIG. 24, a trim process is performed on the element separation film 90 and the element separation pattern 9.

The trim process may be performed to remove a part of the side surface of the element separation film 90 and a part of the side surface of the element separation pattern 9. A first portion 90_1 and a second portion 90_2 of the element separation film 90 may be formed. A step (S1 of FIG. 10) may be formed between the first portion 90_1 and the second portion 90_2 of the element separation film 90. A first portion 9_1 and a second portion 9_2 of the element separation pattern 9 may be formed. A step (S2 of FIG. 11) may be formed between the first portion 9_1 and the second portion 9_2 of the element separation pattern 9.

Subsequent procedures may be substantially the same as those described with respect to FIGS. 18 to 23. The product of FIG. 9 may be formed by a manufacturing process to which a trim process is added.

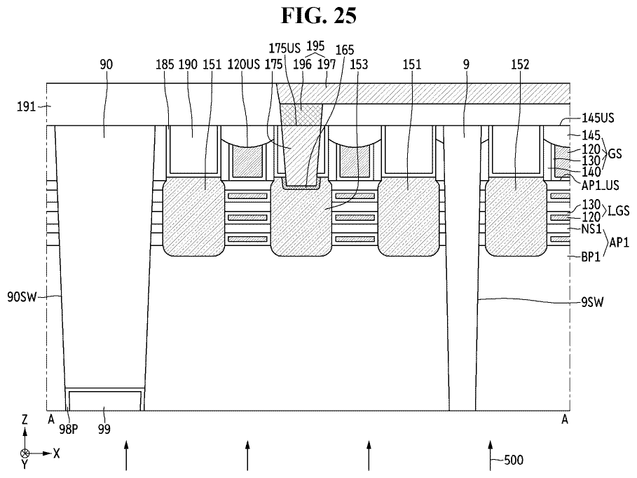

FIGS. 25 to 27 are intermediate stage diagrams for describing a method for manufacturing a semiconductor device according to some embodiments of the present disclosure. For convenience of description, repeated contents of those explained in FIGS. 15 to 23 will be briefly described or omitted. FIGS. 25 to 27 are diagrams showing the procedures after FIG. 15.

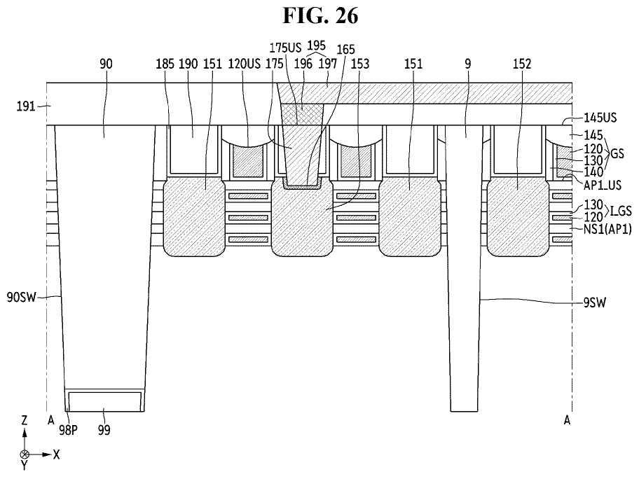

Referring to FIGS. 25 and 26, a part of the lower part of the element separation film 90 is removed to form a pre-capping liner film 98P and a capping insulating film 99, and an etching process 500 is performed.

The pre-capping liner film 98P may be formed along the edge of the region where a part of the element separation film 90 is removed. The capping insulating film 99 may be disposed on the pre-capping liner film 98P. The pre-capping liner film 98P and the capping insulating film 99 may include an insulating material. As an example, the pre-capping liner film 98P may include silicon oxide, and the capping insulating film 99 may include silicon nitride.

The lower pattern BP1 may be removed by the etching process 500. The lower pattern BP1 may be removed to expose the source/drain patterns 151, 152, and 153 and the gate insulating film 130.

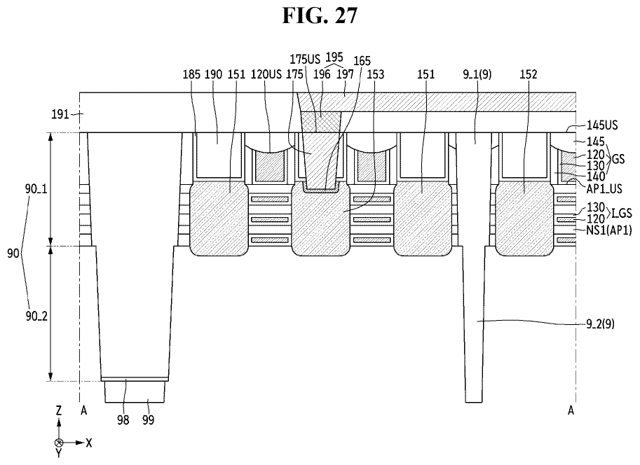

Referring to FIG. 27, a trim process is then performed.

After the trim process, the side surface of the element separation film 90 and the side surface of the element separation pattern 9 may be partially removed. Also, after the trim process is performed, a part of the pre-capping liner film 98P may be removed to form the capping liner film 98. After the trim process, a part of the side surface of the capping insulating film 99 may be removed. The width of the capping insulating film 99 in the first direction X may be smaller than the width of the capping liner film 98 in the first direction X.

Subsequent procedures may be substantially the same as those explained with respect to FIGS. 18 to 23. The manufacturing procedures of FIGS. 25 to 27 may be added to form the product of FIG. 12.

Example embodiments of the present disclosure have been described hereinabove with reference to the accompanying drawings, but the present disclosure is not limited to the above-described example embodiments, and may be implemented in various different forms, and one of ordinary skill in the art to which the present disclosure pertains may understand that the present disclosure may be implemented in other specific forms without changing the technical spirit or essential features of the present disclosure. Therefore, it is to be understood that the example embodiments described above are illustrative rather than being restrictive in all aspects.

What is claimed is:

1. A semiconductor device comprising:
a lower interlayer insulating layer including a first surface and a second surface that are opposite to each other in a first direction;
a plurality of active patterns disposed on the first surface of the lower interlayer insulating layer and spaced apart from each other in the first direction;
a gate structure that is disposed on the first surface of the lower interlayer insulating layer and wraps each of the plurality of active patterns, the gate structure including a gate electrode and a gate insulating film;
a source/drain pattern, the source/drain pattern being connected to the plurality of active patterns;
a lower conductive layer that is disposed on the second surface of the lower interlayer insulating layer, and includes a first surface and a second surface that are opposite to each other in the first direction, the first surface of the lower conductive layer being in contact with the lower interlayer insulating layer;
a lower source/drain contact, the lower source/drain contact protruding from the lower conductive layer in the first direction and being connected to the source pattern or the drain pattern; and
a contact separation pattern that penetrates the lower conductive layer to come into contact with the lower interlayer insulating layer, and overlaps the gate structure in the first direction.

2. The semiconductor device of claim 1, further comprising:
an insulating liner disposed between the lower interlayer insulating layer and the gate structure.

3. The semiconductor device of claim 2,
wherein the insulating liner is in contact with a side surface of the lower source/drain contact.

4. The semiconductor device of claim 2,
wherein the insulating liner includes silicon nitride.

5. The semiconductor device of claim 1,
wherein the contact separation pattern is disposed to be spaced apart from the lower source/drain contact in a second direction, and
a width of the contact separation pattern narrows toward the gate structure.

6. The semiconductor device of claim 1, further comprising:
an element separation film that is spaced apart from the source pattern or the drain pattern in a second direction and extends in the first direction,
wherein the element separation film penetrates the lower interlayer insulating layer and the first surface of the lower conductive layer.

7. The semiconductor device of claim 6,
wherein the element separation film includes a first portion that overlaps the gate structure in the second direction, and a second portion that overlaps the lower interlayer insulating layer in the second direction, and
the first portion and the second portion have a step relative to a level of the first surface of the lower interlayer insulating layer.

8. The semiconductor device of claim 1,
wherein the source pattern or the drain pattern includes a first source/drain pattern, and a second source/drain pattern spaced apart from the first source pattern or drain pattern in a second direction, and
the semiconductor device further includes an element separation pattern which is disposed between the first source pattern or the drain pattern and the second source pattern or the drain pattern, extends in the first direction, and penetrates the lower interlayer insulating layer and the first surface of the lower conductive layer.

9. The semiconductor device of claim 8,
wherein the element separation pattern includes a third portion that overlaps the gate structure in the second direction, and a fourth portion that overlaps the lower interlayer insulating layer in the second direction, and
the third portion and the fourth portion have a step relative to a level of the first surface of the lower interlayer insulating layer.

10. The semiconductor device of claim 1,
wherein a level of an upper surface of the contact separation pattern is lower than a level of the first surface of the lower interlayer insulating layer.

11. The semiconductor device of claim 1,
wherein the lower conductive layer includes a first hole extending from the lower conductive layer to the source pattern or the drain pattern, and
the lower source/drain contact includes a conductive liner film extending along a side wall of the first hole, and a filling film that fills the first hole on the conductive liner film.

12. The semiconductor device of claim 11,
wherein the conductive liner film extends along the first surface of the lower conductive layer and is in contact with a side surface of the contact separation pattern.

13. The semiconductor device of claim 1,
wherein the contact separation pattern is not in contact with the gate structure.

14. A semiconductor device comprising:
a lower interlayer insulating layer including a first surface and a second surface that are opposite to each other in a first direction;
a plurality of active patterns disposed on the first surface of the lower interlayer insulating layer, and spaced apart from each other in the first direction;
a gate structure that is disposed on the first surface of the lower interlayer insulating layer and wraps each of the plurality of active patterns, the gate structure including a gate electrode and a gate insulating film;
a first source/drain pattern and a third source/drain pattern which are disposed with the plurality of active patterns interposed therebetween;
a first lower conductive layer disposed on the second surface of the lower interlayer insulating layer, and overlaps the first source/drain pattern in the first direction;
a second lower conductive layer which is disposed on the second surface of the lower interlayer insulating layer, and overlaps the third source/drain pattern in the first direction;
a lower source/drain contact that protrudes from the first lower conductive layer in the first direction, and is connected to the first source/drain pattern; and
a contact separation pattern that extends in the first direction, and separates the first lower conductive layer from the second lower conductive layer,
wherein the first lower conductive layer includes a first surface and a second surface that are opposite to each other in the first direction,
the first surface of the first lower conductive layer is in contact with the lower interlayer insulating layer,
the second surface of the first lower conductive layer is coplanar with a bottom face of the contact separation pattern, and
a height of the contact separation pattern is smaller than a height from the second surface of the first lower conductive layer to a lowermost part of the gate structure.

15. The semiconductor device of claim 14, further comprising:
an insulating liner disposed between the first surface of the lower interlayer insulating layer and the gate structure.

16. The semiconductor device of claim 14, further comprising:
an element separation film that is spaced apart from the first source/drain pattern in a second direction, and extends in the first direction,
wherein the element separation film penetrates the lower interlayer insulating layer and the first surface of the first lower conductive layer.

17. The semiconductor device of claim 14, further includes a second source/drain pattern spaced apart from the third source/drain pattern in a second direction, and
an element separation pattern which is disposed between the third source/drain pattern and the second source/drain pattern, extends in the first direction, and penetrates the lower interlayer insulating layer and the first and second lower conductive layers.

18. The semiconductor device of claim 14,
wherein a level of an upper surface of the contact separation pattern is the same as a level of upper surfaces of the first and second lower conductive layers.

19. A semiconductor device comprising:
a lower conductive layer;
a lower interlayer insulating layer disposed on an upper surface of the lower conductive layer;
a plurality of active patterns that is disposed on the lower interlayer insulating layer, and spaced apart from the lower interlayer insulating layer in a first direction;
a gate structure that is disposed on the lower interlayer insulating layer and wraps each of the plurality of active pattern, the gate structure including a gate electrode and a gate insulating film;
a source/drain pattern disposed on a side surface of the plurality of active patterns, the source/drain pattern including a first source/drain pattern and a second source/drain pattern spaced apart from the first source/drain pattern in a second direction;
an insulating liner which extends along a profile of the source/drain pattern and the gate structure, between the lower interlayer insulating layer and the source/drain pattern, and between the lower interlayer insulating layer and the gate structure;
a lower source/drain contact that protrudes from the lower conductive layer, penetrates the lower interlayer insulating layer, and is connected to the source/drain pattern;
a contact separation pattern that penetrates the lower conductive layer, overlaps the gate structure in the first direction, and is not in contact with the gate structure;
an element separation film that is spaced apart from the source/drain pattern in the second direction, and penetrates the lower interlayer insulating layer and the lower conductive layer; and
an element separation pattern that is disposed between the first source/drain pattern and the second source/drain pattern, and penetrates the lower interlayer insulating layer and the lower conductive layer,
wherein the insulating liner extends along a part of a side surface of the element separation film and a part of a side surface of the element separation pattern.

20. The semiconductor device of claim 19,
wherein the element separation film includes a first portion that overlaps the gate structure in the second direction, and a second portion that overlaps the lower interlayer insulating layer in the second direction,
the element separation pattern includes a third portion that overlaps the gate structure in the second direction, and a fourth portion that overlaps the lower interlayer insulating layer in the second direction,
the first portion and the second portion have a step relative to a level of the upper surface of the lower interlayer insulating layer, and
the third portion and the fourth portion have a step relative to the level of the upper surface of the lower interlayer insulating layer.
